(19) United States
(12) Patent Application Publication
(10) Pub. No.: US 2025/0070761 A1
(43) Pub. Date: Feb. 27, 2025

(54) N-PATH FILTER

(71) Applicant: Murata Manufacturing Co., Ltd., Nagaokakyo-shi (JP)

(72) Inventor: Hajime KANDO, Nagaokakyo-shi (JP)

(21) Appl. No.: 18/943,045

(22) Filed: Nov. 11, 2024

Related U.S. Application Data
(63) Continuation of application No. PCT/JP2023/020448, filed on Jun. 1, 2023.

(30) Foreign Application Priority Data
Jun. 10, 2022 (JP) 2022-094151

(51) Int. Cl. H03H 19/00; H03H 7/01; H03H 7/42

(52) U.S. Cl. CPC H03H 19/002; H03H 7/0138; H03H 7/42

(57) ABSTRACT

An N-path filter includes first signal paths connected in parallel with each other between signal terminals and second signal paths. Each of the first signal paths includes first and second switches connected to the signal terminals, and a base filter connected between the first and second switches. Each of the second signal paths includes a third switch connected to a signal terminal. The base filter includes a series arm element including a reactance component. The first and second switches modulate an input signal with a phase that completes one cycle across the signal paths, and the third switch modulates the input signal with a phase that completes one cycle across the signal paths. A phase of a drive signal to drive the second switch is opposite to a phase of a drive signal to drive the third switch.

### CROSS REFERENCE TO RELATED APPLICATIONS

This application claims the benefit of priority to Japanese Patent Application No. 2022-094151 filed on Jun. 10, 2022 and is a Continuation Application of PCT Application No. PCT/JP2023/020448 filed on Jun. 1, 2023. The entire contents of each application are hereby incorporated herein by reference.

### BACKGROUND OF THE INVENTION

### 1. Field of the Invention

The present invention relates to N-path filters.

### 2. Description of the Related Art

Japanese Unexamined Patent Application Publication No. 6-237149 discloses a frequency-variable N-path filter. The N-path filter includes N base filters disposed between an input terminal and an output terminal and achieves narrow-band filter characteristics by sequentially switching the N base filters using switches connected to the ends of the N base filters.

An N-path filter capable of changing a flat and low-loss pass band using the driving frequency of switches can be implemented by using an acoustic wave filter, a filter (LC filter) including an inductor and a capacitor, or a filter (dielectric filter) including a dielectric resonator as each of the base filters of the N-path filter described in Japanese Unexamined Patent Application Publication No. 6-237149.

However, when the acoustic wave filter, the LC filter, or the dielectric filter includes a series arm element with an imaginary part (reactance component) in impedance, the time response of a signal is shifted during the switching due to the influence of the imaginary part. Therefore, when a filter including a series arm element with a reactance component is used as each base filter of the N-path filter, all unwanted response modes defined by k. Fck±Fb (Fck: switch driving frequency, Fb: base filter center frequency, k: integer) may occur. As a result, the frequency variable range of the main response mode that does not overlap the frequencies of the unwanted response modes is limited, and it becomes difficult to implement an N-path filter with a desired frequency variable width.

### SUMMARY OF THE INVENTION

Example embodiments of the present invention provide N-path filters that each have a wide frequency variable width and include base filters each of which includes a series arm element with a reactance component.

An N-path filter according to an example embodiment of the present invention includes a first signal terminal, a second signal terminal, and a third signal terminal, N first signal paths that are connected in parallel with each other between the first signal terminal and the second signal terminal, N being an integer greater than or equal to 3, and N second signal paths. Each of the N first signal paths includes a first modulator connected to the first signal terminal to modulate an input signal input from the first signal terminal or the second signal terminal, a second modulator connected to the second signal terminal and to modulate the input signal, and a base filter connected between the first modulator and the second modulator. Each of the N second signal paths connects a node on one of the first signal paths to the third signal terminal and includes a third modulator connected to the third signal terminal to modulate the input signal input from the first signal terminal or the third signal terminal. The base filter includes a series arm element including a reactance component. Each of the first modulator and the second modulator is drivable by one of drive signals that modulate the input signal with a phase that completes one cycle T across the N first signal paths, the third modulator is drivable by one of drive signals that modulate the input signal with a phase that completes one cycle T across the N second signal paths, and the phase of the one of the drive signals to drive the second modulator is opposite to the phase of the one of the drive signals to drive the third modulator.

Example embodiments of the present invention each make it possible to provide an N-path filter that has a wide frequency variable width and includes base filters each of which includes a series arm element with a reactance component.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of an N-path filter according to an example embodiment of the present invention.

FIG. 2 is a timing chart showing drive signals of an N-path filter according to an example embodiment of the present invention.

FIG. 3A is a circuit diagram of an N-path filter according to a first variation of an example embodiment of the present invention.

FIG. 3B is a circuit diagram of an N-path filter according to a second variation of an example embodiment of the present invention.

FIG. 3C is a circuit diagram of an N-path filter according to a third variation of an example embodiment of the present invention.

FIG. 4A is a diagram illustrating an example of a circuit configuration of a base filter according to an example embodiment of the present invention.

FIG. 4B is a graph showing an example of a bandpass characteristic of the base filter alone according to the present example embodiment of the present invention.

FIG. 5 includes graphs showing the bandpass characteristics of the N-path filter according to the present example embodiment of the present invention.

FIG. 6A is a graph showing the bandpass characteristics of the N-path filter according to the first variation of the example embodiment of the present invention.

FIG. 6B is a graph showing the bandpass characteristics near the main response modes of N-path filters according to the first variation and a comparative example.

FIG. 7A is a circuit diagram of the N-path filter according to the comparative example.

FIG. 7B is a graph showing the bandpass characteristics of the N-path filter according to the comparative example.

FIG. 8A is a graph showing response modes when each base filter of an N-path filter is a low pass filter.

FIG. 8B is a graph showing a frequency variable range when each base filter of an N-path filter according to the first variation is a low pass filter and the main response mode is Fck.

FIG. 8C is a graph showing a frequency variable range when each base filter of an N-path filter according to the example embodiment of the present invention is a low pass filter and the main response mode is 2Fck.

FIG. 9A is a graph showing response modes when each base filter of an N-path filter is a band pass filter.

FIG. 9B is a graph showing a frequency variable range when each base filter of an N-path filter according to the first variation is a band pass filter and the main response mode is (Fck
Fb).

FIG. 9C is a graph showing a frequency variable range when each base filter of an N-path filter according to an example embodiment of the present invention is a band pass filter and the main response mode is (2Fck−Fb).

FIG. 10 is a circuit diagram of a radio frequency module and a communication apparatus according to an example embodiment of the present invention.

### DETAILED DESCRIPTION OF THE EXAMPLE EMBODIMENTS

Example embodiments of the present invention are described below with reference to the drawings. Each of the example embodiments described below represents a general or specific example. Values, shapes, materials, components, and layouts and connection configurations of the components described in the example embodiments below are merely examples and are not intended to limit the scope of the present invention. Among the components in the example embodiments described below, components not described in independent claims are optional. Also, the sizes or the ratios of sizes of components illustrated in the drawings are not necessarily accurate.

In the example embodiments described below, unless otherwise described, the pass band of a filter is defined as a frequency band between two frequencies that are about 3 dB greater than the minimum value of insertion loss within the pass band. Also, the center frequency of a filter is defined as the midpoint between the low-end frequency and the high-end frequency of the pass band of the filter ((low-end frequency+high-end frequency)/2).

Also, in the example embodiments described below, the term “signal path” refers to a transmission line including a wire through which a radio frequency signal propagates, circuit elements and electrodes directly connected to the wire, and terminals directly connected to the wire or the electrodes.

In the example embodiments described below, “connected” not only indicates that circuit elements are directly connected to each other with a connection terminal and/or a wire conductor but also indicates that the circuit elements are electrically connected to each other via another circuit element. Also, “connected between A and B” indicates that a component is disposed on a path connecting A to B and is connected to A and B.

In the example embodiments described below, “element A is disposed in series between B and C” means that the signal input end of the element A is connected to a wire, an electrode, or a terminal defining B, and the signal output end of the element A is connected to a wire, an electrode, or a terminal defining C.

### EXAMPLE EMBODIMENTS

### 1. Circuit Configurations of N-Path Filters 1 and 1A

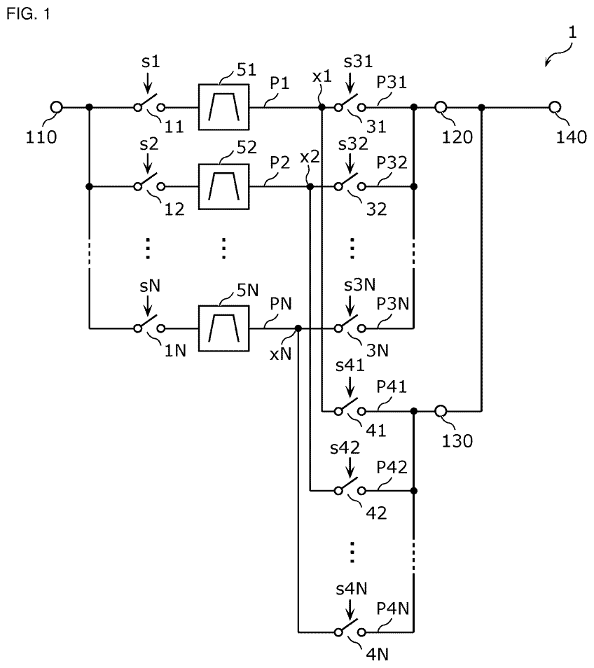

FIG. 1 is a circuit diagram of an N-path filter 1 according to an example embodiment of the present invention. As illustrated in FIG. 1, the N-path filter 1 includes base filters 51 to 5N (N is an integer greater than or equal to 3), switches 11 to 1N (N is an integer greater than or equal to 3), switches 31 to 3N, switches 41 to 4N, a signal terminal 110 (first signal terminal), a signal terminal 120 (second signal terminal), a signal terminal 130 (third signal terminal), and a signal output terminal 140.

The N-path filter 1 includes N first signal paths including signal paths P1, P2, and PN. Signal paths P1 to PN are connected in parallel with each other between the signal terminal 110 and the signal terminal 120. Also, the N-path filter 1 includes N second signal paths including signal paths P41, P42, and P4N. The signal path P41 connects a node x1 on the signal path P1 to the signal terminal 130, the signal path P42 connects a node x2 on the signal path P2 to the signal terminal 130, and the signal path PAN connects a node xN on the signal path PN to the signal terminal 130. That is, each of the N second signal paths connects a node on one of the first signal paths to the signal terminal 130.

The switch 11 is an example of a first switch and is connected to the signal terminal 110 and the base filter 51. The switch 11 is turned on and off by a drive signal s1 based on a driving frequency Fck and thus connects and disconnects the signal terminal 110 to and from the base filter 51.

The switch 31 is an example of a second switch and is connected to the signal terminal 120 and the base filter 51. The switch 31 is turned on and off by a drive signal s31 based on the driving frequency Fck and thus connects and disconnects the signal terminal 120 to and from the base filter 51.

The switch 41 is an example of a third switch and is connected to the signal terminal 130 and the base filter 51. The switch 41 is turned on and off by a drive signal s41 based on the driving frequency Fck and thus connects and disconnects the signal terminal 130 to and from the base filter 51.

The base filter 51 is connected between the switches 11 and 31 and is also connected between the switches 11 and 41.

The switch 12 is an example of a first switch and is connected to the signal terminal 110 and the base filter 52. The switch 12 is turned on and off by a drive signal s2 based on the driving frequency Fck and thus connects and disconnects the signal terminal 110 to and from the base filter 52.

The switch 32 is an example of a second switch and is connected to the signal terminal 120 and the base filter 52. The switch 32 is turned on and off by a drive signal s32 based on the driving frequency Fck and thus connects and disconnects the signal terminal 120 to and from the base filter 52.

The switch 42 is an example of a third switch and is connected to the signal terminal 130 and the base filter 52. The switch 42 is turned on and off by a drive signal s42 based on the driving frequency Fck and thus connects and disconnects the signal terminal 130 to and from the base filter 52.

The base filter 52 is connected between the switches 12 and 32 and is also connected between the switches 12 and 42.

The switch 1N is an example of a first switch and is connected to the signal terminal 110 and the base filter 5N. The switch 1N is turned on and off by a drive signal sN based on the driving frequency Fck and thus connects and disconnects the signal terminal 110 to and from the base filter 5N.

The switch 3N is an example of a second switch and is connected to the signal terminal 120 and the base filter 5N. The switch 3N is turned on and off by a drive signal s3N based on the driving frequency Fck and thus connects and disconnects the signal terminal 120 to and from the base filter 5N.

The switch 4N is an example of a third switch and is connected to the signal terminal 130 and the base filter 5N. The switch 4N is turned on and off by a drive signal s4N based on the driving frequency Fck and thus connects and disconnects the signal terminal 130 to and from the base filter 5N.

The base filter 5N is connected between the switches 1N and 3N and is also connected between the switches 1N and 4N.

Each of the switches 11-1N, 31-3N, and 41-4N is provided by, for example, a complementary metal oxide semiconductor (CMOS).

The base filter 51 and the switches 11 and 31 define the signal path P1. The base filter 52 and the switches 12 and 32 define the signal path P2. The base filter 5N and the switches 1N and 3N define the signal path PN.

Also, the switch 41 defines the signal path P41. The switch 42 defines the signal path P42. The switch 4N defines the signal path P4N.

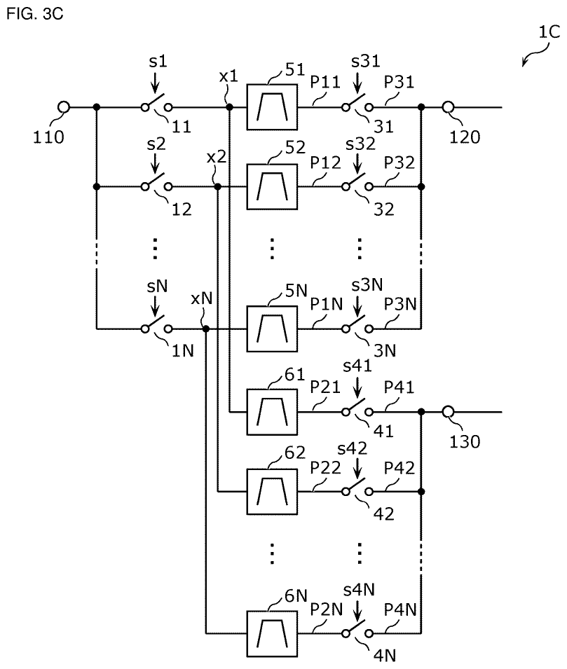

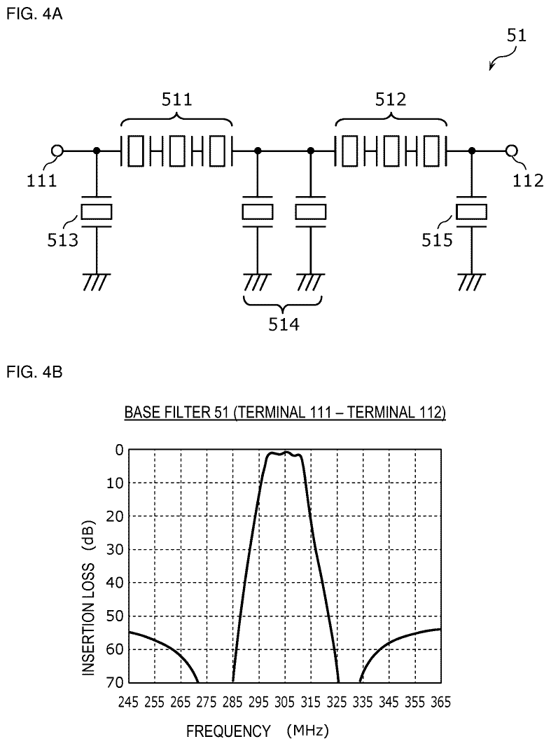

Each of the base filters 51 to 5N includes a series arm element with a reactance component (the imaginary part in impedance). Here, the series arm element is a circuit element that is disposed in series in a path connecting the input end and the output end of the base filter. Examples of circuit configurations and bandpass characteristics of the base filters 51 to 5N are described below with reference to FIGS. 4A and 4B.

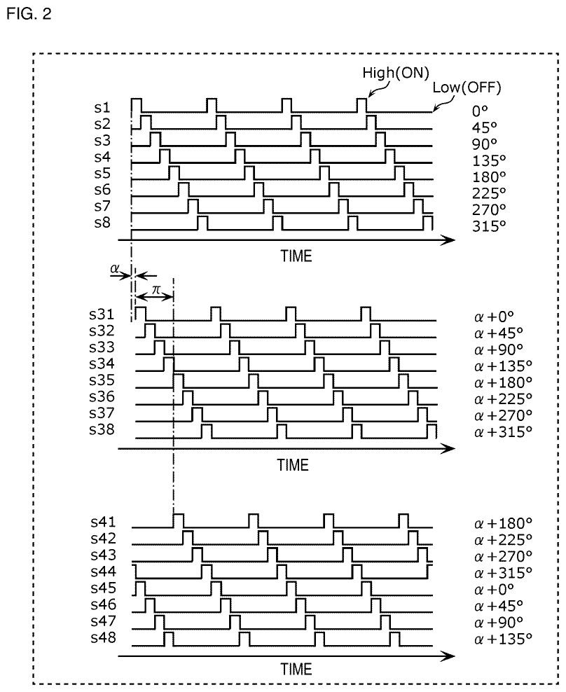

FIG. 2 is a timing chart showing drive signals of the N-path filter 1 according to the present example embodiment. FIG. 2 shows examples of drive signals s1 to s8 supplied to the switches 11 to 1N (when N=8), drive signals s31 to s38 supplied to the switches 31 to 3N (when N=8), and drive signals s41 to s48 supplied to the switches 41 to 4N (when N=8). The drive signals s1 to s8, s31 to s38, and s41 to s48 are generated based on the driving frequency Fck (clock signal). When a drive signal is high, the corresponding switch becomes conductive (ON), and when a drive signal is low, the corresponding switch becomes non-conductive (OFF). More specifically, each of the cycle of the drive signals s1 to s8, the cycle of the drive signals s31 to s38, and the cycle of the drive signals s41 to s48 is represented by T. Here, when each of the phase difference between the drive signals s1 and s31, the phase difference between the drive signals s2 and s32, and the phase difference between the drive signals s8 and s38 is represented by a, the phase relationship among the drive signals is expressed by formulas 1 below. In Formulas 1, N is an integer from 1 to 8, and a is any appropriate value.

$$( Formula 1 )$$

$$Phase of drive signal s N = ( N - 1 ) \times 2 π / 8$$

$$Phase of drive signal s 3 N = ( N - 1 ) \times 2 π / 8 + α$$

$$Phase of drive signal s 4 N = ( N - 1 ) \times 2 π / 8 + α + π$$

The first switches (the switches 11 to 1N) are driven, respectively, by the drive signals s1 to sN that modulate an input signal with a phase that completes one cycle T across the N first signal paths (the signal paths P1 to PN). Also, the second switches (the switches 31 to 3N) are driven, respectively, by the drive signals s31 to s3N that modulate an input signal with a phase that completes one cycle T across the N first signal paths (the signal paths P1 to PN). Furthermore, the third switches (the switches 41 to 4N) are driven, respectively, by the drive signals s41 to s4N that modulate an input signal with a phase that completes one cycle T across the N second signal paths (the signal paths P41 to P4N).

When the switches are driven by the drive signals, the N-path filter 1 defines and functions as a band pass filter with a center frequency Frf defined by Formula 2 below.

$$Frf = k \cdot Fck \pm Fb \qquad ( Formula 2 )$$

In Formula 2, Fb is the center frequency of each base filter, and k is an integer. According to formula 2, the N-path filter 1 defines and functions as a band pass filter whose pass band can be varied by changing the driving frequency Fck. Accordingly, the bandpass characteristics of the N-path filter 1 include multiple pass bands (and multiple attenuation bands) corresponding to the values of k. When each base filter is a low pass filter, Fb is zero.

Here, according to the phase relationships indicated by Formulas 1, at a frequency (1/T+Fb), the phases of the drive signals s3N for driving the second switches (the switches 31 to 3N) are opposite (with a phase difference n) to the phases of the drive signals s4N for driving the third switches (the switches 41 to 4N).

In the N-path filter according to example embodiments of the present invention, the phase difference between the drive signals s3N and s4N need not be strictly n) (180°. In the N-path filter according to example embodiments of the present invention, two signals being in opposite phase means that the phase difference between two signals falls within, for example, about 1800±5%.

In the N-path filter 1 according to the present example embodiment, each of the switches 11 to 1N may be, for example, a first modulator that modulates an input signal input from the signal terminal 110 or 120. Also, each of the switches 31 to 3N may be, for example, a second modulator that modulates an input signal input from the signal terminal 110 or 120. Furthermore, each of the switches 41 to 4N may be, for example, a third modulator that modulates an input signal input from the signal terminal 110 or 130. Specifically, the first modulators and the second modulators are driven, respectively, by drive signals that modulate an input signal with a phase that completes one cycle T across the N first signal paths. The third modulators are driven, respectively, by drive signals that modulate an input signal with a phase that completes one cycle T across the N second signal paths. Each of the switches 11 to 1N is an example of the first modulator, each of the switches 31 to 3N is an example of the second modulator, and each of the switches 41 to 4N is an example of the third modulator. However, the first modulators, the second modulators, and the third modulators may be provided by, for example, mixers instead of the switches 11 to 1N, the switches 31 to 3N, and the switches 41 to 4N.

In the N-path filter 1 illustrated in FIG. 1, a transfer function T from the signal terminal 110 to the signal terminal 120 is represented by Formula 3, in which G represents the transfer function of each base filter, ω represents each frequency, and ω_{ck} represents the frequency of each drive signal.

$$T ( k {ω}_{ck} + Δ ω ) = {sinc}^{2} ( \frac{k π}{N} ) G ( Δ ω ) \qquad ( Formula 3 )$$

Transfer functions Hₖₐ from the signal terminal 110 to the signal terminal 120 and transfer functions H_{kb} from the signal terminal 110 to the signal terminal 130 at frequencies (k ω_{ck}+Δ_{ω}) are represented by Formulas 4 below.

$$( Formulas 4 )$$

$${H}_{0 a} ( 0 {ω}_{c k} + Δ ω ) = {e}^{0} T ( 0 {ω}_{c k} + Δ ω ) = T ( 0 {ω}_{c k} + Δ ω ) \qquad ( k = 0 )$$

$${H}_{0 b} ( 0 {ω}_{c k} + Δ ω ) = - {e}^{j π} T ( 0 {ω}_{ck} + Δ ω ) = T ( 0 {ω}_{c k} + Δ ω ) \qquad ( k = 0 )$$

$${H}_{1 a} ( 1 {ω}_{c k} + Δ ω ) = {e}^{0} T ( 1 {ω}_{ck} + Δ ω ) = T ( 1 {ω}_{ck} + Δ ω ) \qquad ( k = 1 )$$

$${H}_{1 b} ( 1 {ω}_{c k} + Δ ω ) = - {e}^{0} T ( 1 {ω}_{ck} + Δ ω ) = - T ( 1 {ω}_{c k} + Δ ω ) \qquad ( k = 1 )$$

$${H}_{2 a} ( 2 {ω}_{c k} + Δ ω ) = {e}^{0} T ( 2 {ω}_{c k} + Δ ω ) = T ( 2 {ω}_{ck} + Δ ω ) \qquad ( k = 2 )$$

$${H}_{2 b} ( 2 {ω}_{ck} + Δ ω ) = - {e}^{j π} T ( 2 {ω}_{ck} + Δ ω ) = T ( 2 {ω}_{c k} + Δ ω ) \qquad ( k = 2 )$$

$${H}_{3 a} ( 3 {ω}_{ck} + Δ ω ) = {e}^{0} T ( 3 {ω}_{ck} + Δ ω ) = T ( 3 {ω}_{ck} + Δ ω ) \qquad ( k = 3 )$$

$${H}_{3 b} ( 3 {ω}_{ck} + Δ ω ) = - {e}^{0} T ( 3 {ω}_{ck} + Δ ω ) = - T ( 3 {ω}_{ck} + Δ ω ) \qquad ( k = 3 )$$

Formulas 4 show that when k is an even number (including 0), the values of the transfer functions Hₖₐ and H_{kb} become the same or substantially the same, and the phase of a signal transmitted from the signal terminal 110 to the signal terminal 120 becomes the same or substantially the same as the phase of a signal transmitted from the signal terminal 110 to the signal terminal 130.

Formulas 4 also show that when k is an odd number, the values of the transfer functions Hₖₐ and H_{kb} have opposite signs, and the phase of a signal transmitted from the signal terminal 110 to the signal terminal 120 becomes opposite to the phase of a signal transmitted from the signal terminal 110 to the signal terminal 130.

Accordingly, as illustrated in FIG. 1, when the signal output from the signal terminal 120 is added to the signal output from the signal terminal 130 and k is an odd number, Hₖₐ+H_{kb} becomes 0, and modes where the values of k are odd numbers can be reduced or prevented.

When a filter including a series arm element with a reactance component is used as each base filter of an N-path filter, all unwanted response modes defined by k. Fck±Fb (Fck: switch driving frequency, Fb: base filter center frequency, k: integer) occur. As a result, the frequency variable range of the main response mode that does not overlap the frequencies of the unwanted response modes is limited, and it becomes difficult to provide an N-path filter with a desired frequency variable width.

In contrast, with the configuration of the N-path filter 1 according to the present example embodiment, unwanted response modes that occur when the values of k are odd numbers can be reduced or prevented by adding signals output from the signal terminals 120 and 130 together. Accordingly, the N-path filter 1, which is defined by base filters each including a series arm element with a reactance component, can have a wide frequency variable width.

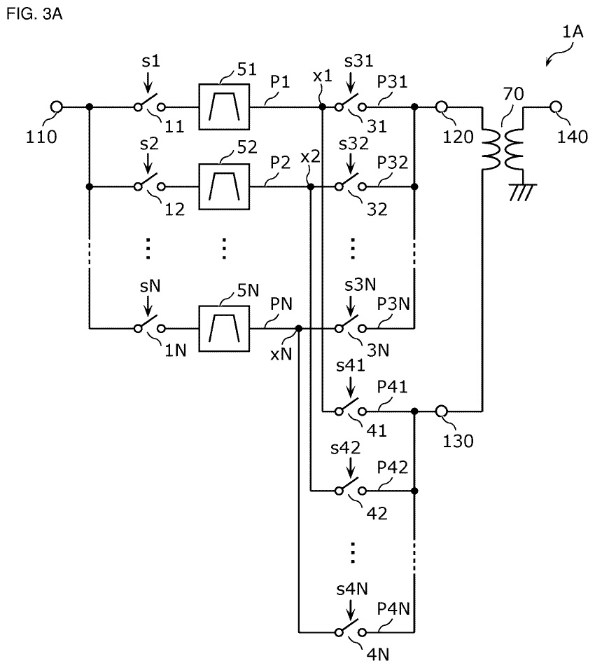

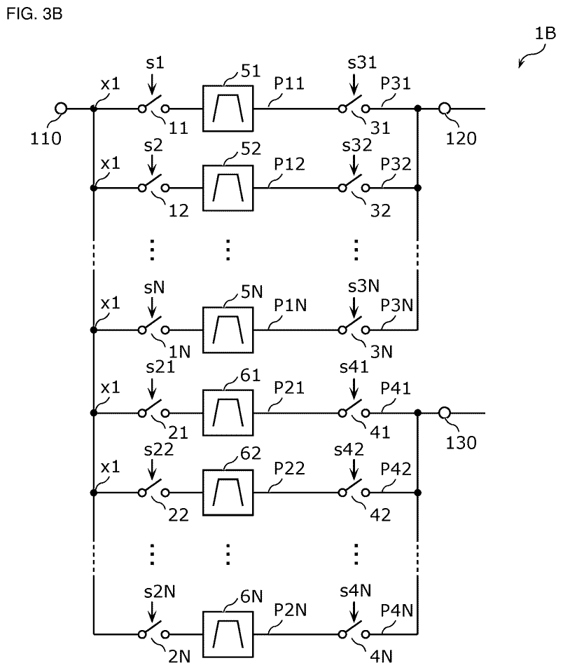

Also, when the signal output from the signal terminal 130 is subtracted from the signal output from the signal terminal 120 and k is an even number (including 0), Hₖₐ-H_{kb} becomes 0, and modes where the values of k are even numbers (including 0) can be reduced or prevented. This can be achieved by an N-path filter 1A illustrated in FIG. 3A.

FIG. 3A is a circuit diagram of the N-path filter 1A according to a first variation of the present example embodiment. As illustrated in FIG. 3A, the N-path filter 1A includes base filters 51 to 5N (N is an integer greater than or equal to 3), switches 11 to 1N, switches 31 to 3N, switches 41 to 4N, a signal terminal 110 (first signal terminal), a signal terminal 120 (second signal terminal), a signal terminal 130 (third signal terminal), a balun 70, and a signal output terminal 140. The N-path filter 1A according to the present variation differs from the N-path filter 1 according to the above-described example embodiment only in that the balun 70 is provided between the signal terminals 120 and 130 and the signal output terminal 140. Below, only configurations of the N-path filter 1A of the present variation different from those of the N-path filter 1 of the above-described example embodiment are described.

The Balun 70 is an example of a balanced-unbalanced conversion element and includes a primary coil and a secondary coil that are electromagnetically coupled to each other. One of the balanced terminals of the primary coil is connected to the signal terminal 120, the other one of the balanced terminals of the primary coil is connected to the signal terminal 130, the unbalanced terminal of the secondary coil is connected to the signal output terminal 140, and the other end of the secondary coil is connected to the ground. With this configuration, the signal output from the signal terminal 120 and the signal output from the signal terminal 130 become two differential signals, and a signal obtained by combining the voltages of the differential signals is output to the signal output terminal 140. The balanced-unbalanced conversion element is not limited to a balun but may also be, for example, a transformer or a semiconductor circuit.

With the configuration of the N-path filter 1A according to the first variation, unwanted response modes where the values of k are even numbers (including 0) can be reduced or prevented by subtracting the signal output from the signal terminal 130 from the signal output from the signal terminal 120. Accordingly, the N-path filter 1A, which includes base filters each including a series arm element with a reactance component, can have a wide frequency variable width.

In the N-path filter 1 according to the above-described example embodiment and the N-path filter 1A according to the first variation, the signal terminal 110 is used as a signal input terminal to which an input signal is supplied, and the signal output terminal 140 is used as a signal output terminal from which an output signal is output. However, the flow of signals may be reversed. That is, the signal output terminal 140 may be used as a signal input terminal to which an input signal is supplied, and the signal terminal 110 may be used as a signal output terminal from which an output signal is output.

Next, specific ranges of the phase difference between the drive signals s3N and s4N in the N-path filter 1 according to the above-described example embodiment and the N-path filter 1A according to the first variation are described.

In an exemplary case described below, in the N-path filter 1 according to the example embodiment illustrated in FIG. 1, it is assumed that (H₁ₐ-H_{1b}) is the main mode, and (H₀ₐ-H_{0b}) and (H₂ₐ-H_{2b}), which are close to (H₁ₐ-H_{1b}), are unwanted modes.

In this case, for example, the range of the phase difference is preferably greater than or equal to about 174.261° and less than or equal to about 185.739°. When 180±5.739 (greater than or equal to about 174.261° and less than or equal to about) 185.739° is substituted for π in Formulas 4, Formulas 4 are expressed as Formulas 5 below.

$$( Formulas 5 )$$

$${H}_{0 a} - {H}_{0 b} = {e}^{0} T ( 0 {ω}_{c k} + Δ ω ) - {e}^{j ( \frac{0 ( 180 \pm 5.739 )}{180} π )} T ( 0 {ω}_{ck} + Δ ω ) = 0$$

$${H}_{2 a} - {H}_{2 b} = {e}^{0} T ( 2 {ω}_{c k} + Δ ω ) - {e}^{j ( \frac{2 ( 180 \pm 5.739 )}{180} π )} T ( 2 {ω}_{ck} + Δ ω ) = ( 0. 0200 + j 0.199 ) T ( 2 {ω}_{c k} + Δ ω )$$

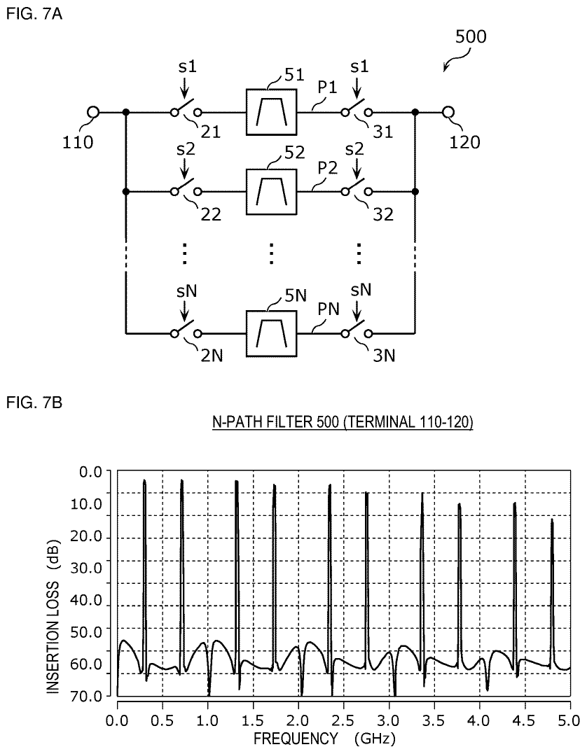

As indicated by Formulas 5, (H₀ₐ−H_{0b}) becomes 0, and no response occurs. Also, compared to the unwanted mode (H₂ₐ−H_{2b}) that occurs with the related-art N-path filter (an N-path filter 500 illustrated in FIG. 7A described below), the unwanted mode (H₂ₐ−H_{2b}) can be reduced or prevented by, for example, about 20 dB (20 log 10 ((0.0200-j0.1990)/2)).

In another exemplary case, in the N-path filter 1A according to the first variation illustrated in FIG. 3A, it is assumed that (H₂ₐ+H_{2b}) is the main mode, and (H₁ₐ+H_{1b}) and (H₃ₐ+H_{3b}), which are close to (H₂ₐ+H_{2b}), are unwanted modes.

In this case, the range of the phase difference is, for example, preferably greater than or equal to about 176.174° and less than or equal to about 183.826°. When 180±3.826 (greater than or equal to about 176.174° and less than or equal to about) 183.826° is substituted for n in Formulas 4, compared to the unwanted mode (H₁ₐ+H_{1b}) that occurs with the related-art N-path filter (the N-path filter 500 illustrated in FIG. 7A described below), the unwanted mode (h₁ₐ−H_{1b}) can be reduced or prevented by, for example, about 29.5 dB. Also, compared to the unwanted mode (H₁ₐ−H_{1b}) that occurs with the related-art N-path filter (the N-path filter 500 illustrated in FIG. 7A described below), the unwanted mode (H₃ₐ−H_{3b}) can be reduced or prevented by, for example, about 20 dB.

Here, for example, the suppression level of about 20 dB is equivalent to the minimum attenuation required for a reception filter and a transmission filter used for a high frequency region greater than or equal to about 500 MHz. When the attenuation of about 20 dB or more can be achieved by the transmission filter and the reception filter, signal leakage from a transmitter circuit to a receiver circuit can be made less than or equal to about-40 dB and the degradation of receiver sensitivity due to the signal leakage can be maintained within an acceptable range by combining a circulator or a canceller circuit with the transmission filter and the reception filter.

Here, in each of the N-path filter 1 according to the above-described example embodiment and the N-path filter 1A according to the first variation, a phase shift rotation circuit may be connected to, for example, the signal terminals 110 and 120 to prevent the phase difference from being shifted from the reverse phase. For example, the phase shift rotation circuit may be configured such that a first end of the phase shift rotation circuit is connected to the signal terminal 110 or 120, a second end of the phase shift rotation circuit is grounded, multiple capacitors are connected in parallel with the first end and the second end, and specific capacitors are connected by switches.

### 2. Circuit Configurations of N-Path Filters 1B and 1C

FIG. 3B is a circuit diagram of an N-path filter 1B according to a second variation of the above-described example embodiment. As illustrated in FIG. 3B, the N-path filter 1B includes base filters 51 to 5N (N is an integer greater than or equal to 3), base filters 61 to 6N, switches 11 to 1N, switches 21 to 2N, switches 31 to 3N, switches 41 to 4N, a signal terminal 110 (first signal terminal), a signal terminal 120 (second signal terminal), and a signal terminal 130 (third signal terminal). The N-path filter 1B according to the present variation differs from the N-path filter 1 according to the above-described example embodiment in that the base filters 61 to 6N and the switches 21 to 2N are added. Below, configurations of the N-path filter 1B of the present variation different from those of the N-path filter 1 of the above-described example embodiment are mainly described. Although the signal output terminal 140 is not illustrated in FIG. 3B, the signal terminals 120 and 130 may be connected to the signal output terminal 140 as in FIG. 1, or the signal terminals 120 and 130 may be connected to the signal output terminal 140 via the balun 70 as in FIG. 3A.

The N-path filter 1B includes N first signal paths including signal paths P11, P12, and PIN. The signal paths P11 to PIN are connected in parallel with each other between the signal terminal 110 and the signal terminal 120. The N-path filter 1B also includes N second signal paths including signal paths P21, P22, and P2N. The signal path P21 connects a node x1 on the signal path P11 to the signal terminal 130, the signal path P22 connects a node x1 on the signal path P12 to the signal terminal 130, and the signal path P2N connects a node x1 on the signal path PIN to the signal terminal 130. That is, each of the N second signal paths connects a node on one of the first signal paths to the signal terminal 130.

The switch 21 is connected to the signal terminal 110 and the base filter 61. The switch 21 is turned on and off by a drive signal s21 based on the driving frequency Fck and thereby connects and disconnects the signal terminal 110 to and from the base filter 61.

The switch 41 is an example of a third switch and is connected to the signal terminal 130 and the base filter 61. The switch 41 is turned on and off by a drive signal s41 based on the driving frequency Fck and thereby connects and disconnects the signal terminal 130 to and from the base filter 61.

The base filter 61 is connected between the switches 21 and 41.

The switch 22 is connected to the signal terminal 110 and the base filter 62. The switch 22 is turned on and off by a drive signal s22 based on the driving frequency Fck and thereby connects and disconnects the signal terminal 110 to and from the base filter 62.

The switch 42 is an example of a third switch and is connected to the signal terminal 130 and the base filter 62. The switch 42 is turned on and off by a drive signal s42 based on the driving frequency Fck and thereby connects and disconnects the signal terminal 130 to and from the base filter 62.

The base filter 62 is connected between the switches 22 and 42.

The switch 2N is connected to the signal terminal 110 and the base filter 6N. The switch 2N is turned on and off by a drive signal s2N based on the driving frequency Fck and thereby connects and disconnects the signal terminal 110 to and from the base filter 6N.

The switch 4N is an example of a third switch and is connected to the signal terminal 130 and the base filter 6N. The switch 4N is turned on and off by a drive signal s4N based on the driving frequency Fck and thereby connects and disconnects the signal terminal 130 to and from the base filter 6N.

The base filter 6N is connected between the switches 2N and 4N.

The base filter 51 and the switches 11 and 31 define the signal path P11. The base filter 52 and the switches 12 and 32 define the signal path P12. The base filter 5N and the switches 1N and 3N define the signal path PIN.

The base filter 61 and the switches 21 and 41 define the signal path P21. The base filter 62 and the switches 22 and 42 define the signal path P22. The base filter 6N and the switches 2N and 4N define the signal path P2N.

Each of the base filters 61 to 6N includes a series arm element with a reactance component (the imaginary part in impedance).

In the N-path filter 1B according to the present variation, when, for example, N=8 and a indicates each of the phase difference between the drive signal sN and the drive signal s3N and the phase difference between the drive signal s2N and the drive signal s4N, the phase relationship among the drive signals is represented by Formulas 6 below.

$$( Formulas 6 )$$

$$Phase of drive signal s N = ( N - 1 ) \times 2 π / 8$$

$$Phase of drive signal s 2 N = ( N - 1 ) \times 2 π / 8$$

$$Phase of drive signal s 3 N = ( N - 1 ) \times 2 π / 8 + α$$

$$Phase of drive signal s 4 N phase = ( N - 1 ) \times 2 π / 8 + α + π$$

FIG. 3C is a circuit diagram of an N-path filter 1C according a third variation of the above-described example embodiment. As illustrated in FIG. 3C, the N-path filter 1C includes base filters 51 to 5N (N is an integer greater than or equal to 3), base filters 61 to 6N, switches 11 to 1N, switches 31 to 3N, switches 41 to 4N, a signal terminal 110 (first signal terminal), a signal terminal 120 (second signal terminal), and a signal terminal 130 (third signal terminal). The N-path filter 1C according to the present variation differs from the N-path filter 1 according to the above-described example embodiment in that the base filters 61 to 6N are added. Below, configurations of the N-path filter 1C of the present variation different from those of the N-path filter 1 of the above-described example embodiment are mainly described. Although the signal output terminal 140 is not illustrated in FIG. 3C, the signal terminals 120 and 130 may be connected to the signal output terminal 140 as in FIG. 1, or the signal terminals 120 and 130 may be connected to the signal output terminal 140 via the balun 70 as in FIG. 3A.

The N-path filter 1C includes N first signal paths including signal paths P11, P12, and PIN. The signal paths P11 to PIN are connected in parallel with each other between the signal terminal 110 and the signal terminal 120. Also, the N-path filter 1C includes N second signal paths including signal paths P21, P22, and P2N. The signal path P21 connects a node x1 on the signal path P11 to the signal terminal 130, the signal path P22 connects a node x2 on the signal path P12 to the signal terminal 130, and the signal path P2N connects a node xN on the signal path PIN to the signal terminal 130. That is, each of the N second signal paths connects a node on one of the first signal paths to the signal terminal 130.

The switch 41 is an example of a third switch and is connected to the signal terminal 130 and the base filter 61. The switch 41 is turned on and off by a drive signal s41 based on the driving frequency Fck and thus connects and disconnects the signal terminal 130 to and from the base filter 61.

The base filter 61 is connected between the switches 11 and 41.

The switch 42 is an example of a third switch and is connected to the signal terminal 130 and the base filter 62. The switch 42 is turned on and off by a drive signal s42 based on the driving frequency Fck and thus connects and disconnects the signal terminal 130 to and from the base filter 62.

The base filter 62 is connected between the switches 12 and 42.

The switch 4N is an example of a third switch and is connected to the signal terminal 130 and the base filter 6N. The switch 4N is turned on and off by a drive signal s4N based on the driving frequency Fck and thus connects and disconnects the signal terminal 130 to and from the base filter 6N.

The base filter 6N is connected between the switches 1N and 4N.

The base filter 51 and the switches 11 and 31 define the signal path P11. The base filter 52 and the switches 12 and 32 define the signal path P12. The base filter 5N and the switches 1N and 3N define the signal path PIN.

The base filter 61 and the switch 41 define the signal path P21. The base filter 62 and the switch 42 define the signal path P22. The base filter 6N and the switch 4N define the signal path P2N.

Each of the base filters 61 to 6N includes a series arm element with a reactance component (the imaginary part in impedance).

In the N-path filter 1C according to the present variation, when, for example, N=8 and a indicates the phase difference between the drive signal sN and the drive signal s3N, the phase relationship among the drive signals is represented by Formulas 1.

### 3. Circuit Configuration and Bandpass Characteristic of Base Filter

FIG. 4A is a diagram illustrating an example of a circuit configuration of the base filter 51 according to the present example embodiment. FIG. 4A illustrates an example of a circuit configuration of the base filter 51 among the base filters 51 to 5N. The circuit configurations of the base filters 52 to 5N are the same or substantially the same as the circuit configuration of the base filter 51 illustrated in FIG. 4A.

As illustrated in FIG. 4A, the base filter 51 includes acoustic wave resonators 511, 512, 513, 514, and 515.

The acoustic wave resonators 511 and 512 are series arm resonators connected in series with each other between terminals 111 and 112. The acoustic wave resonator 513 is a parallel arm resonator connected between the terminal 111 and the ground. The acoustic wave resonator 515 is a parallel arm resonator connected between the terminal 112 and the ground. The acoustic wave resonator 514 is a parallel arm resonator connected between the ground and nodes on the path that connects the acoustic wave resonators 511 and 512 to each other.

Each of the acoustic wave resonators 511 and 512 includes three split resonators connected in series with each other. Also, the acoustic wave resonator 514 includes two split resonators connected in parallel with each other.

Each of the acoustic wave resonators 511 and 512 is a series arm element with a reactance component (the imaginary part in impedance).

With the above configuration, the base filter 51 illustrated in FIG. 4A is, for example, a ladder acoustic wave band-pass filter. In the base filters 51 to 5N according to the present example embodiment, each of the acoustic wave resonators 511 to 515 is a resonator using a surface acoustic wave and uses, for example, a LiNbO₃ single-crystal substrate (hereafter referred to as LN) with −4° Y-cut X-propagation as a substrate with piezoelectricity. The resonant frequency of the acoustic wave resonators 511 and 512 is set on the higher frequency side than the resonant frequency of the acoustic wave resonators 513 and 514. Here, for example, in the N-path filter 1, N is set to 8, and the terminal impedance at the terminal 111 (on the side closer to the signal terminal 110) of each of the base filters 51 to 5N is designed to be about 400Ω.

Also, in the N-path filter 1, when Z₀ indicates the terminal impedance at the signal terminal 110 and Zb indicates the input/output impedance of the base filters 51 to 5N, a reflection coefficient (Zb−N×Z₀)/(Zb+N×Z₀) preferably satisfies the relationship indicated by Formula 7 below.

$$( Zb - N \times {Z}_{0} ) / ( Zb + N \times {Z}_{0} ) < 0.316 \qquad ( Formula 7 )$$

In the N-path filter 1, the terminal impedance at the terminal 111 (on the side closer to the signal terminal 110) of each of the base filters 51 to 5N is designed to be about 400Ω, and the reflection coefficient becomes ideally 0 when Z₀=about 50Ω, Zb=about 400Ω, and N=8 are substituted in Formula 7.

When the impedance of the N-path filter 1 seen from the signal terminal 120 toward the signal terminal 110 is Z1 and the impedance of the N-path filter 1 seen from the signal terminal 130 toward the signal terminal 110 is Z2 (=Z1), the impedance matching between the signal terminals 120 and 130 can be achieved by setting input/output impedance Zb1 of the terminal 112 (the side closer to the signal terminal 120) of each of the base filters 51 to 5N to Z1×N/2 and setting input/output impedance Zb2 of the terminal 112 (the side closer to the signal terminal 130) of each of the base filters 51 to 5N to Z2×N/2.

With the N-path filter 1 according to the present example embodiment, for example, the return loss at the signal terminals 110, 120, and 130 can be reduced or prevented to a value less than about 10 dB, and therefore the mismatching loss with external connection circuits connected to the signal terminals 110, 120, and 130 can be reduced or prevented. Accordingly, the N-path filter 1 can be used for a radio-frequency front-end circuit that transmits a radio frequency signal with low loss.

In the N-path filter 1B of the second variation and the N-path filter 1C of the third variation, the number of base filters is about twice that of the N-path filter 1 according to the present example embodiment. Accordingly, the terminal impedance of each base filter at the signal terminal 110 becomes about twice the input/output impedance Zb of each of the base filters 51 to 5N of the N-path filter 1.

FIG. 4B is a graph showing an example of a bandpass characteristic of the base filter 51 alone according to the present example embodiment. As shown in FIG. 4B, for example, the base filter 51 is a band pass filter with a center frequency of about 305 MHz and a band width of about 10 MHz.

Instead of the acoustic wave filter illustrated in FIG. 4A, each of the base filters 51 to 5N may be provided by a filter including an inductor and a capacitor (a LC filter) or a filter including a dielectric resonator (a dielectric filter). By using acoustic wave filters, LC filters, or dielectric filters as the base filters, it is possible to provide the N-path filter 1 that can change a flat and low-loss pass band using the driving frequency Fck of the switches.

### 4. Bandpass Characteristics of N-Path Filter

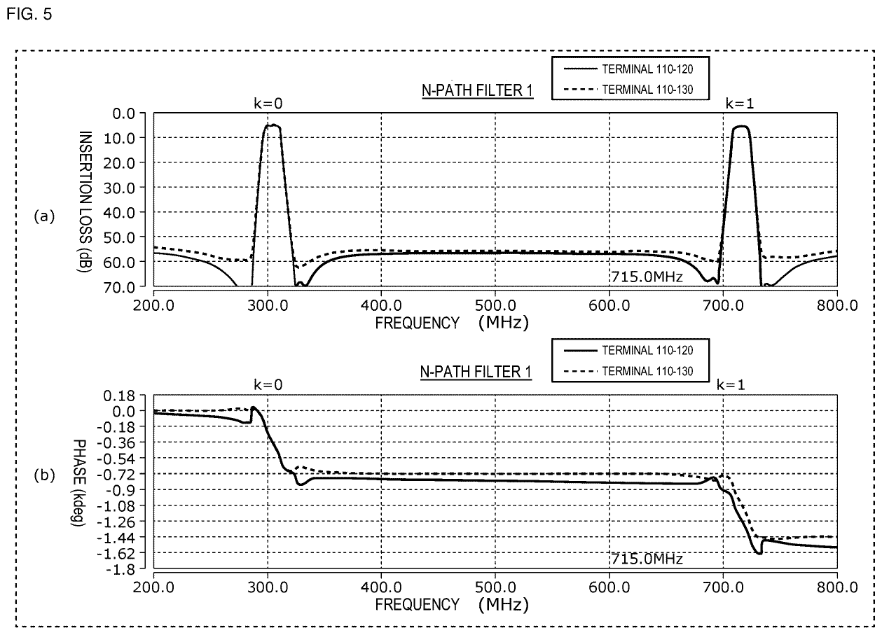

FIG. 5 includes graphs showing the bandpass characteristics of the N-path filter 1 according to the present example embodiment. FIG. 5 shows the characteristics of the N-path filter 1 illustrated in FIG. 1 when, for example, the driving frequency Fck is about 1020 MHz, the surface acoustic wave filter (center frequency Fb: about 305 MHz) illustrated in FIG. 4A is used as each base filter, and N is 8. Part (a) of FIG. 5 shows the amplitude characteristics (solid line) between the signal terminals 110 and 120 and the amplitude characteristics (dotted line) between the signal terminals 110 and 130. Part (b) of FIG. 5 shows the phase characteristics (solid line) between the signal terminals 110 and 120 with respect to an input signal and the phase characteristics (dotted line) between the signal terminals 110 and 130 with respect to the input signal.

In FIG. 5, for example, responses at about 305 MHZ (=0×Fck±Fb), where k=0 (even number), are in phase and have the same or substantially the same amplitudes, and responses at about 715 MHZ (=1×Fck−Fb), where k=1 (odd number), are in opposite phase and have the same or substantially the same amplitudes. In part (b) of FIG. 5, for example, the phase between the signal terminals 110 and 120 at about 715 MHz is about −1229.8°, and the phase between the signal terminals 110 and 130 at about 715 MHz is about −1049.9°.

Thus, with the circuit configuration of the N-path filter 1 illustrated in FIG. 1, the signals of the signal terminal 120 and the signal terminal 130 are added together, and modes where the values of k are odd numbers can be reduced or prevented. Also, with the circuit configuration of the N-path filter 1A illustrated in FIG. 3A, the signal of the signal terminal 130 is subtracted from the signal of the signal terminal 120, and modes where the values of k are even numbers can be reduced or prevented.

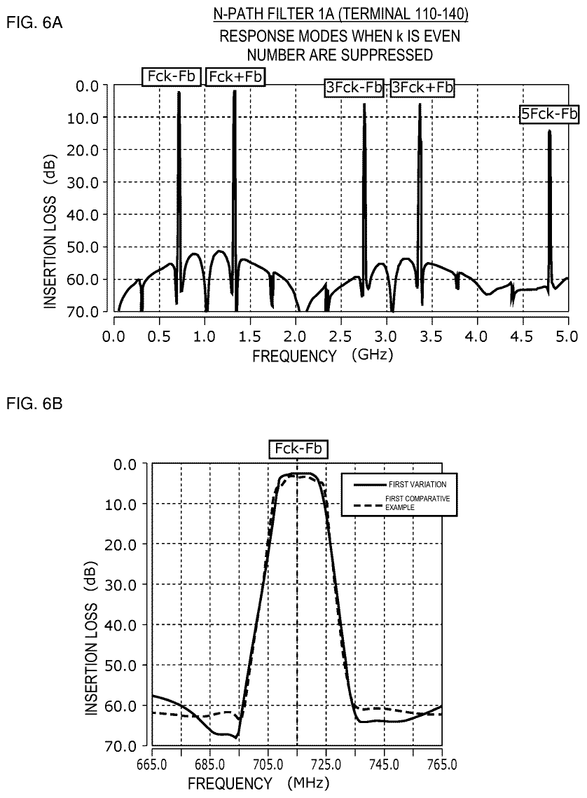

FIG. 6A is a graph showing the bandpass characteristics of the N-path filter 1A according to a first variation of an example embodiment of the present invention. FIG. 6A shows the characteristics of the N-path filter 1A illustrated in FIG. 3A when, for example, the driving frequency Fck is about 1020 MHZ, the surface acoustic wave filter (center frequency Fb: about 305 MHz) illustrated in FIG. 4A is used as each base filter, and N is 8. As shown in FIG. 6A, with the N-path filter 1A capable of reducing or preventing modes where the values of k are even numbers, response modes (0×Fck±Fb), (2×Fck±Fb), and (4×Fck±Fb) are reduced or prevented, and response modes (1×Fck±Fb), (3×Fck±Fb), and (5×Fck±Fb), where the values of k are odd numbers, occur.

FIG. 6B is a graph showing the bandpass characteristics near the main response modes of the N-path filter 1A of the first variation and an N-path filter 500 of a comparative example. The circuit configuration and bandpass characteristics in a wider band of the N-path filter 500 according to the comparative example are shown in FIGS. 7A and 7B.

FIG. 7A is a circuit diagram of the N-path filter 500 according to the comparative example. FIG. 7B is a graph showing the bandpass characteristics of the N-path filter 500 according to the comparative example. The N-path filter 500 includes base filters 51 to 5N (N is an integer greater than or equal to 3), switches 21 to 2N, switches 31 to 3N, and signal terminals 110 and 120. The N-path filter 500 according to the comparative example differs from the N-path filter 1 according to the example embodiment in that each pair of the switches 21 to 2N and the switches 31 to 3N are turned on and off at the same time and the switches 41 to 4N are not provided. Below, configurations of the N-path filter 500 of the comparative example different from those of the N-path filter 1 of the example embodiment are mainly described.

The switch 21 is connected to the signal terminal 110 and the base filter 51. The switch 21 is turned on and off by a drive signal s1 based on the driving frequency Fck and thus connects and disconnects the signal terminal 110 to and from the base filter 51.

The switch 31 is connected to the signal terminal 120 and the base filter 51. The switch 31 is turned on and off by the drive signal s1 based on the driving frequency Fck at the same time as the switch 21 and thus connects and disconnects the signal terminal 120 to and from the base filter 51.

The switch 22 is connected to the signal terminal 110 and the base filter 52. The switch 22 is turned on and off by a drive signal s2 based on the driving frequency Fck and thus connects and disconnects the signal terminal 110 to and from the base filter 52.

The switch 32 is connected to the signal terminal 120 and the base filter 52. The switch 32 is turned on and off by the drive signal s2 based on the driving frequency Fck at the same time as the switch 22 and thus connects and disconnects the signal terminal 120 to and from the base filter 52.

The switch 2N is connected to the signal terminal 110 and the base filter 5N. The switch 2N is turned on and off by a drive signal sN based on the driving frequency Fck and thus connects and disconnects the signal terminal 110 to and from the base filter 5N.

The switch 3N is connected to the signal terminal 120 and the base filter 5N. The switch 3N is turned on and off by the drive signal sN based on the driving frequency Fck at the same time as the switch 2N and thus connects and disconnects the signal terminal 120 to and from the base filter 5N.

The base filter 51 and the switches 21 and 31 define a signal path P1. The base filter 52 and the switches 22 and 32 define a signal path P2. The base filter 5N and the switches 2N and 3N define a signal path PN.

For the N-path filter 500, the drive signals s1 to sN to drive the switches 21 to 2N and the switches 31 to 3N are generated based on the driving frequency Fck. More specifically, when the cycle of the drive signals s1 to sN is T, each of the drive signals s1 to sN is turned on for a period T/N, and the drive signals s1 to sN are sequentially turned on at intervals of T/N. As a result, the switches 21 to 2N are turned on at different times in the cycle T depending on the signal paths. Also, the switches 31 to 3N are turned on at different times in the cycle T depending on the signal paths. That is, the base filters 51 to 5N are connected to the signal terminals 110 and 120 at different times in the cycle T depending on the signal paths.

With the above configuration, the N-path filter 500 defines and functions as a band pass filter with the center frequency Frf defined by Formula 2.

According to Formula 2, the N-path filter 500 defines and functions as a band pass filter whose pass band can be changed by changing the driving frequency Fck. Accordingly, the bandpass characteristics of the N-path filter 500 include multiple pass bands (and multiple attenuation bands) corresponding to the values of k.

As illustrated in FIG. 7B, with the N-path filter 500 according to the comparative example, response modes (k. Fck±Fb) defined by Formula 2 occur.

Compared with the N-path filter 500 of the comparative example with which unwanted responses are not reduced or prevented, with the N-path filter 1A of the first variation with which unwanted responses are reduced or prevented, the insertion loss within the pass band in the main response mode (Fck−Fb) is reduced and the attenuation in the vicinity of the pass band is increased as shown in FIG. 6B.

### 5. Frequency Variable Range of Main Response Mode

With the N-path filter 1 (including the N-path filter 1A) according to the present example embodiment, when an unwanted response overlapping the main response exists, an unwanted signal caused by the unwanted response is transmitted. To prevent the transmission of the unwanted signal, it is preferable that the frequencies of the main response and the unwanted response do not overlap each other.

Below, the frequency variable range of the main response mode when a low pass filter is used for each base filter and the frequency variable range of the main response mode when a band pass filter is used for each base filter are described.

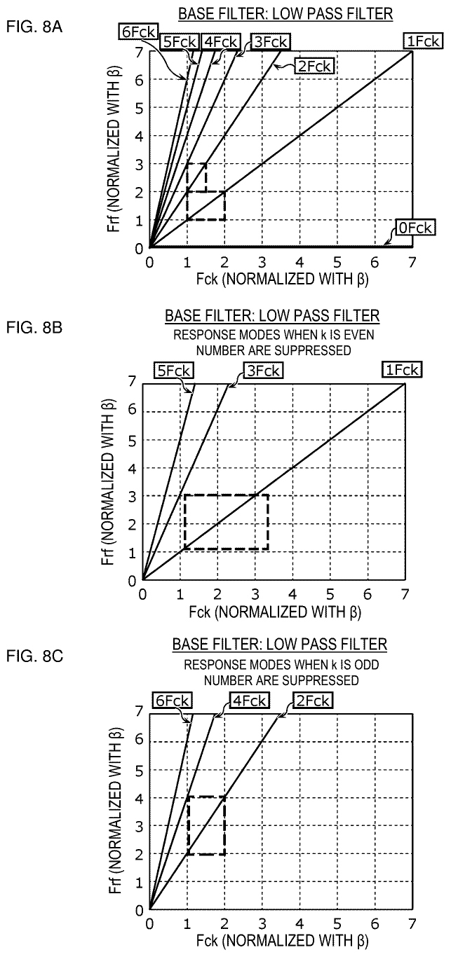

FIG. 8A is a graph showing response modes when the base filters of the N-path filters 1 and 1A are low pass filters. FIG. 8A shows the relationship represented by Formula 2 when response modes are not reduced or prevented. When the base filters are low pass filters, Fb=0. In FIG. 8A, the horizontal axis represents Fck (=Fck/β) normalized by a constant β (>0), and the vertical axis represents Frf (=Frf/β) normalized by the constant β. As shown in FIG. 8A, the center frequency Frf of the N-path filters 1 and 1A can be changed by changing the driving frequency Fck. For example, when (1×Fck) is used as the main response mode, the variable frequency range of the center frequency Frf, with which no unwanted response mode occurs at the lower end of the variable frequency, is greater than or equal to β and less than or equal to 2β when β≤Fck≤2β and is, for example, about 0.5 GHZ to about 1 GHz. Also, when (2×Fck) is used as the main response mode, the variable frequency range of the center frequency Frf, with which no unwanted response mode occurs at the lower end of the variable frequency, is, for example, greater than or equal to about 2β and less than or equal to about 3β when β≤Fck≤1.5β.

FIG. 8B is a graph showing the frequency variable range of the main response mode (1×Fck) when the base filters of the N-path filter 1A of the first variation are low pass filters. The N-path filter 1A according to the first variation can reduce or prevent response modes when the values of k are even numbers and can thus reduce the number of unwanted response modes. For example, when (1×Fck) is used as the main response mode, modes (0×Fck) and (2×Fck) are reduced or prevented. Therefore, the variable frequency range of the center frequency Frf, with which no unwanted response mode occurs at the lower end of the variable frequency, is greater than or equal to about β and less than or equal to about 3β when β≤Fck≤33 and is, for example, about 0.5 GHZ to about 1.5 GHz. Thus, compared with the case of FIG. 8A in which response modes where the values of k are even numbers are not reduced or prevented, an approximately twofold frequency variable width can be achieved.

FIG. 8C is a graph showing the frequency variable range of the main response mode (2×Fck) when the base filters of the N-path filter 1 of the present example embodiment are low pass filters. The N-path filter 1 according to the present example embodiment can reduce or prevent response modes where the values of k are odd numbers and can thereby reduce the number of unwanted response modes. For example, when (2×Fck) is used as the main response mode, modes (1×Fck) and (3×Fck) are reduced or prevented. Therefore, for example, the variable frequency range of the center frequency Frf, with which no unwanted response mode occurs at the lower end of the variable frequency, is greater than or equal to about 2β and less than or equal to about 43 when β≤Fck≤2β. Thus, compared with the case of FIG. 8A in which response modes where the values of k are odd numbers are not reduced or prevented, an approximately twofold frequency variable width can be achieved.

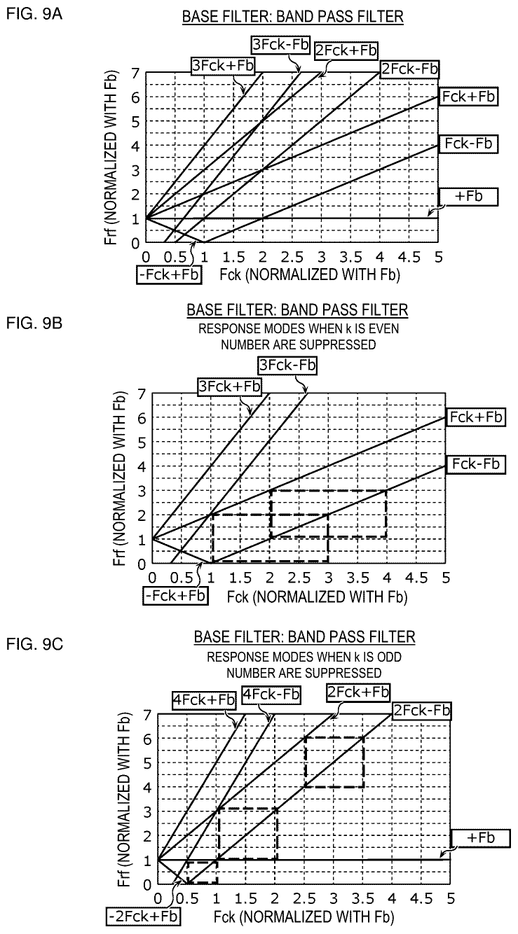

FIG. 9A is a graph showing response modes when the base filters of the N-path filters 1 and 1A are band pass filters. FIG. 9A shows the relationship represented by Formula 2 when response modes are not reduced or prevented. In FIG. 9A, the horizontal axis represents Fck normalized with the center frequency Fb of each base filter (=Fck/Fb), and the vertical axis represents Frf normalized with the center frequency Fb (=Frf/Fb). As shown in FIG. 9A, the center frequency Frf of the N-path filters 1 and 1A can be changed by changing the driving frequency Fck. For example, when (1×Fck±Fb) is used as the main response mode, the variable frequency range of the driving frequency Fck, with which no unwanted response mode occurs at the lower end and the upper end of the variable frequency, is represented by Formulas 8 below.

$$Fc k > 2 Fb , \qquad ( Formula s 8 )$$

$$Fck\_max + Fb < 2 Fck\_min - Fb , and$$

$$Fck\_max - Fb < Fck\_min + Fb$$

Also, for example, when (1×Fck−Fb) is used as the main response mode, the frequency range of the driving frequency Fck, with which no unwanted response mode occurs at the lower end and the upper end of the variable frequency, is represented by Formulas 9 below.

$$( Formulas 9 )$$

$$Fck\_min + Fb > Fck\_max - Fb and Fck > 2 Fb , and$$

$$1 Fb < Fck < 2 Fb$$

Fck_min is the driving frequency of switches at the lower limit of the frequency variable range using the main response mode, and Fck max is the driving frequency of switches at the upper limit of the frequency variable range using the main response mode.

FIG. 9B is a graph showing the frequency variable ranges of the main response modes (1×Fck−Fb) and (1×Fck±Fb) when the base filters of the N-path filter 1A according to the first variation are band pass filters. The N-path filter 1A of the first variation can reduce or prevent response modes where the values of k are even numbers. Therefore, when, for example, (1×Fck−Fb) is used as the main response mode, mode (0×Fck±Fb) is reduced or prevented. Therefore, the frequency range of the driving frequency Fck, with which no unwanted response mode occurs at the lower end and the upper end of the variable frequency, is represented by Formulas 10 below.

$$( Formulas 10 )$$

$$Fck > Fb , and$$

$$Fck\_max < 2 Fck\_min + 2 Fb$$

That is, the number of unwanted response modes can be reduced by reducing or preventing response modes where the values of k are even numbers, and compared with the frequency range defined by FIG. 9A and Formulas 9 where response modes are not reduced or prevented, the frequency variable range of the center frequency Frf of the N-path filter 1A can be widened.

Also, for example, when (1×Fck±Fb) is used as the main response mode, modes (0×Fck±Fb) and (2×Fck−Fb) are reduced or prevented, and the frequency range of the driving frequency Fck, with which no unwanted response mode occurs at the lower end and the upper end of the variable frequency, is represented by Formulas 11 below.

$$( Formulas 11 )$$

$$Fck > Fb ,$$

$$2 Fck\_min - Fb < Fck\_max + Fb , and$$

$$Fck\_min + Fb < Fck\_max - Fb$$

That is, the number of unwanted response modes can be reduced by reducing or preventing response modes where the values of k are even numbers, and compared with the frequency range defined by FIG. 9A and Formulas 8 where response modes are not reduced or prevented, the frequency variable range of the center frequency Frf of the N-path filter 1A can be widened.

FIG. 9C is a graph showing the frequency variable ranges of the main response modes (2×Fck−Fb) and (2×Fck±Fb) when the base filters of the N-path filter 1 according to the present example embodiment are band pass filters. The N-path filter 1 according to the example embodiment can suppress response modes where the values of k are odd numbers. Accordingly, when, for example, (2×Fck−Fb) is used as the main response mode, mode (1×Fck±Fb) is reduced or prevented. Therefore, the frequency range of the driving frequency Fck, with which no unwanted response mode occurs at the lower end and the upper end of the variable frequency, is represented by Formulas 12 below.

$$( Formulas 12 )$$

$$0.5 \times Fb < Fck < Fb , and$$

$$Fck > Fb and 2 Fck\_min + Fb > 2 Fck\_max - Fb$$

That is, the number of unwanted response modes can be reduced by reducing or preventing response modes where the values of k are even numbers, and compared with the frequency range defined by FIG. 9A where response modes are not reduced or prevented, the frequency variable range of the center frequency Frf of the N-path filter 1 can be widened.

Also, for example, when (2×Fck±Fb) is used as the main response mode, modes (3×Fck±Fb) and (1×Fck−Fb) are reduced or prevented, and the frequency range of the driving frequency Fck, with which no unwanted response mode occurs at the lower end and the upper end of the variable frequency, is represented by Formula 13 below.

$$( Formula 13 )$$

$$Fck > Fb and 4 Fck\_min - Fb > 2 Fck\_max + Fb$$

That is, the number of unwanted response modes can be reduced by reducing or preventing response modes where the values of k are odd numbers, and compared with the frequency range defined by FIG. 9A where response modes are not reduced or prevented, the frequency variable range of the center frequency Frf of the N-path filter 1 can be widened.

6. Circuit Configurations of Radio Frequency Module 5 and Communication Apparatus 10 According to Example Embodiment

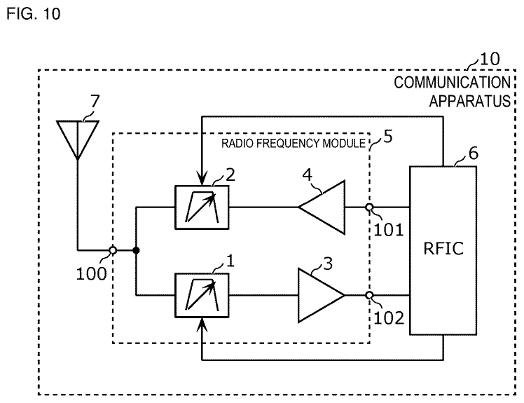

FIG. 10 is a circuit diagram of a radio frequency module 5 and a communication apparatus 10 according to an example embodiment of the present invention. As illustrated in FIG. 10, the communication apparatus 10 includes the radio frequency module 5, an RF signal processing circuit (RFIC) 6, and an antenna 7.

The radio frequency module 5 transmits radio frequency signals between the antenna 7 and the RFIC 6. The antenna 7 is connected to an antenna connection terminal 100 of the radio frequency module 5, transmits a radio frequency signal output from the radio frequency module 5, receives a radio frequency signal from the outside, and outputs the received radio frequency signal to the radio frequency module 5.

The RFIC 6 is an example of a signal processing circuit that processes radio frequency signals. Specifically, the RFIC 6 performs signal processing, such as down-converting, for example, on a radio-frequency reception signal input via a reception path of the radio frequency module 5 and outputs a reception signal generated by the signal processing to a baseband signal processing circuit (BBIC) (not shown). Also, the RFIC 6 performs signal processing, such as up-converting, on a transmission signal from the BBIC and outputs a radio-frequency transmission signal generated by the signal processing to a transmission path of the radio frequency module 5. The RFIC 6 includes a controller that controls, for example, N-path filters 1 and 2 and amplifiers included in the radio frequency module 5. Some or all of the functions of the controller of the RFIC 6 may be provided outside of the RFIC 6 and may be implemented by, for example, components in the BBIC or the radio frequency module 5.

In the communication apparatus 10 according to the present example embodiment, the antenna 7 is not an essential component.

Next, a circuit configuration of the radio frequency module 5 is described. As illustrated in FIG. 10, the radio frequency module 5 includes N-path filters 1 and 2, a power amplifier 4, a low-noise amplifier 3, an antenna connection terminal 100, a radio frequency input terminal 101, and a radio frequency output terminal 102.

The antenna connection terminal 100 is connected to the antenna 7. The radio frequency input terminal 101 is connected to the RFIC 6 and receives a radio-frequency transmission signal from the RFIC 6. The radio frequency output terminal 102 is connected to the RFIC 6 and outputs a radio-frequency reception signal to the RFIC 6.

The N-path filter 1 is one of the N-path filter 1 according to the present example embodiment, the N-path filter 1A according to the first variation, the N-path filter 1B according to the second variation, and the N-path filter 1C according to the third variation, and is a reception filter connected between the antenna connection terminal 100 and the low-noise amplifier 3. The N-path filter 1 can change the pass band and the attenuation band according to drive signals s1 to sN, s21 to s2N, s31 to s3N, and s41 to s4N that are output from the RFIC 6. With this configuration, the N-path filter 1 can selectively pass radio frequency signals in multiple bands.

The N-path filter 2 is one of the N-path filter 1 according to the present example embodiment, the N-path filter 1A according to the first variation, the N-path filter 1B according to the second variation, and the N-path filter 1C according to the third variation, and is a transmission filter connected between the antenna connection terminal 100 and the power amplifier 4. The N-path filter 2 can change the pass band and the attenuation band according to drive signals s1 to sN, s21 to s2N, s31 to s3N, and s41 to s4N that are output from the RFIC 6. With this configuration, the N-path filter 2 can selectively pass radio frequency signals in multiple bands.

A drive circuit that outputs the drive signals s1 to sN, s21 to s2N, s31 to s3N, and s41 to s4N may be included in the controller of the RFIC 6, may be included in the radio frequency module 5, or may be provided as a semiconductor integrated circuit (IC) separately from the radio frequency module 5 and the RFIC 6.

The low-noise amplifier 3 is connected between the N-path filter 1 and the radio frequency output terminal 102 and amplifies a reception signal input from the antenna connection terminal 100.

The power amplifier 4 is connected between the N-path filter 2 and the radio frequency input terminal 101 and amplifies a transmission signal input from the radio frequency input terminal 101.

With the above configuration, it is not necessary to provide filters for respective multiple bands, and only one N-path filter supporting the multiple bands needs to be provided. This in turn makes it possible to reduce the sizes of the radio frequency module 5 and the communication apparatus 10.

The radio frequency module 5 and the communication apparatus 10 may also include, for example, impedance matching elements and switches in addition to the circuit elements illustrated in FIG. 10.

Also, the radio frequency module 5 may also include, for example, multiple power amplifiers and switches for changing the connections between the multiple power amplifiers and the N-path filter 2. Furthermore, the radio frequency module 5 may include multiple low-noise amplifiers and switches for changing the connections between the multiple low-noise amplifiers and the N-path filter 1.

### OTHER EXAMPLE EMBODIMENTS

N-path filters according to example embodiments of the present invention and variations thereof are described above. However, the present invention is not limited to the above-described example embodiments and variations. The present invention may also include variations obtained by making various modifications conceivable by a person skilled in the art to the example embodiments without departing from the scope and spirit of the present invention, and various apparatuses including the N-path filters according to example embodiments of the present invention.

Also, for example, matching elements, such as inductors and capacitors, and switch circuits may be connected between the components of each of the N-path filters according to example embodiments.

Example embodiments of the present invention can be used for a wide variety of communication devices, such as, for example, mobile phones, as a low-loss and high-attenuation filter applicable to multiband and multimode frequency standards.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An N-path filter comprising:
a first signal terminal, a second signal terminal, and a third signal terminal;
N first signal paths that are connected in parallel with each other between the first signal terminal and the second signal terminal, N being an integer greater than or equal to 3; and
N second signal paths; wherein
each of the N first signal paths includes:
a first modulator connected to the first signal terminal to modulate an input signal input from the first signal terminal or the second signal terminal;
a second modulator connected to the second signal terminal to modulate the input signal; and
a base filter connected between the first modulator and the second modulator;
each of the N second signal paths connects a node on one of the first signal paths to the third signal terminal and includes a third modulator connected to the third signal terminal to modulate the input signal input from the first signal terminal or the third signal terminal;
the base filter includes a series arm element including a reactance component;
each of the first modulator and the second modulator is drivable by one of drive signals that modulate the input signal with a phase that completes one cycle T across the N first signal paths;
the third modulator is drivable by one of drive signals that modulate the input signal with a phase that completes one cycle T across the N second signal paths; and
a phase of the one of the drive signals to drive the second modulator is opposite to a phase of the one of the drive signals to drive the third modulator.

2. The N-path filter according to claim 1, wherein a difference between the phase of the one of the drive signals to drive the second modulator and the phase of the one of the drive signals to drive the third modulator is greater than or equal to about 174.261° and less than or equal to about 185.739°.

3. The N-path filter according to claim 1, wherein
the first modulator includes a first switch connecting and disconnecting the first signal terminal to and from the base filter according to the one of the drive signals;
the second modulator includes a second switch connecting and disconnecting the second signal terminal to and from the base filter according the one of the drive signals; and
the third modulator includes a third switch connecting and disconnecting the third signal terminal to and from the base filter according to the one of the drive signals.

4. The N-path filter according to claim 1, further comprising:
a signal input terminal and a signal output terminal; wherein
the signal input terminal is the first signal terminal; and
the signal output terminal is connected to the second signal terminal and the third signal terminal.

5. The N-path filter according to claim 1, further comprising:
a signal input terminal and a signal output terminal; and
a balanced-unbalanced conversion element including two balanced terminals and one unbalanced terminal; wherein
the signal input terminal is the first signal terminal;
one of the two balanced terminals is connected to the second signal terminal;
another one of the two balanced terminals is connected to the third signal terminal; and
the signal output terminal is connected to the unbalanced terminal.

6. The N-path filter according to claim 1, wherein the base filter is one of an acoustic wave filter, a filter including an inductor and a capacitor, or a filter including a dielectric resonator.

7. The N-path filter according to claim 1, wherein, when Z₀ is a terminal impedance at the first signal terminal of the N-path filter and Zb is an input/output impedance on a side of the base filter closer to the first signal terminal, a relationship represented by (Zb−N×Z₀)/(Zb+N×Z₀)<about 0.316 is satisfied.

8. The N-path filter according to claim 5, wherein the balanced-unbalanced conversion element includes a Balun including a primary coil and a secondary coil.

9. The N-path filter according to claim 1, wherein a difference between the phase of the one of the drive signals to drive the second modulator and the phase of the one of the drive signals to drive the third modulator is greater than or equal to about 176.173° and less than or equal to about 183.826°.

10. A radio frequency module comprising:
at least one N-path filter according to claim 1; and
at least one amplifier connected to the at least one N-path filter.

11. The radio frequency module according to claim 10, wherein a difference between the phase of the one of the drive signals to drive the second modulator and the phase of the one of the drive signals to drive the third modulator is greater than or equal to about 174.261° and less than or equal to about 185.739°.

12. The radio frequency module according to claim 10, wherein
the first modulator includes a first switch connecting and disconnecting the first signal terminal to and from the base filter according to the one of the drive signals;
the second modulator includes a second switch connecting and disconnecting the second signal terminal to and from the base filter according the one of the drive signals; and
the third modulator includes a third switch connecting and disconnecting the third signal terminal to and from the base filter according to the one of the drive signals.

13. The radio frequency module according to claim 10, wherein
each of the at least one N-path filter includes:
a signal input terminal and a signal output terminal; wherein
the signal input terminal is the first signal terminal; and
the signal output terminal is connected to the second signal terminal and the third signal terminal.

14. The radio frequency module according to claim 10, wherein
each of the at least one N-path filter includes:
a signal input terminal and a signal output terminal; and
a balanced-unbalanced conversion element including two balanced terminals and one unbalanced terminal; wherein
the signal input terminal is the first signal terminal;
one of the two balanced terminals is connected to the second signal terminal;
another one of the two balanced terminals is connected to the third signal terminal; and
the signal output terminal is connected to the unbalanced terminal.

15. The radio frequency module according to claim 10, wherein the base filter is one of an acoustic wave filter, a filter including an inductor and a capacitor, or a filter including a dielectric resonator.

16. The radio frequency module according to claim 10, wherein, when Z₀ is a terminal impedance at the first signal terminal of the N-path filter and Zb is an input/output impedance on a side of the base filter closer to the first signal terminal, a relationship represented by (Zb−N×Z₀)/(Zb+N×Z₀)<about 0.316 is satisfied.

17. The radio frequency module according to claim 14, wherein the balanced-unbalanced conversion element includes a Balun including a primary coil and a secondary coil.

18. The radio frequency module according to claim 10, wherein a difference between the phase of the one of the drive signals to drive the second modulator and the phase of the one of the drive signals to drive the third modulator is greater than or equal to about 176.173° and less than or equal to about 183.826°.
